(19) United States
(12) Patent Application Publication
(10) Pub. No.: US 2023/0401357 A1
(43) Pub. Date: Dec. 14, 2023

(54) OBJECT PACKING GENETIC PROCEDURES

(71) Applicants: Hewlett-Packard Development Company, L.P., Spring, TX (US); INSTITUTO ATLANTICO, Bairro Edson Queiroz (BR)

(72) Inventors: JUAN CARLOS CATANA SALAZAR, GUADALAJARA (MX); ALYNE GOMES SOARES CANTAL, PORTO ALEGRE (BR); JORGE ALBERTO BECERRA VELAZQUEZ, GUADALAJARA (MX); ANDRE LUIZ LIMA PEDRO, PORTO ALEGRE (BR); SCOTT ALAN WHTE, BOISE, ID (US); JUN ZENG, PALO ALTO, CA (US)

(21) Appl. No.: 18/036,586

(22) PCT Filed: Dec. 14, 2020
(86) PCT No.: PCT/US2020/064913

§ 371 Date: May 11, 2023

(51) Int. Cl. G06F 30/20; B33Y 10/00; B33Y 50/00; B29C 64/386

(52) U.S. Cl. CPC G06F 30/20; B33Y 10/00; B33Y 50/00; B29C 64/386

(57) ABSTRACT

Examples of methods for object packing genetic procedures are described herein. In some examples, a method includes generating chromosomes in a genetic procedure. In some examples, each chromosome indicates a packing of objects in a volume. In some examples, the method includes determining a stagnant generation quantity that indicates an amount of generations subsequent to a leading generation with a leading chromosome score. In some examples, the method includes terminating the genetic procedure based on the stagnant generation quantity.

### BACKGROUND

Three-dimensional (3D) solid objects may be produced from a digital model using manufacturing. Additive manufacturing is an example of manufacturing. Additive manufacturing may be used in rapid prototyping, mold generation, mold master generation, and short-run manufacturing. Additive manufacturing involves the application of successive layers of build material. In some additive manufacturing techniques, the build material may be cured or fused. Other machining processes remove material to create the final object.

### BRIEF DESCRIPTION OF THE DRAWINGS

FIG. 1 is a flow diagram illustrating an example of a method for object packing genetic procedures;

FIG. 2 is a block diagram of an example of an apparatus that may be used in object packing genetic procedures;

FIG. 3 is a block diagram illustrating an example of a computer-readable medium for object packing genetic procedures; and

FIG. 4 is a diagram illustrating an example of a user interface.

### DETAILED DESCRIPTION

Additive manufacturing may be used to manufacture three-dimensional (3D) objects. 3D printing is an example of additive manufacturing. Performing additive manufacturing may rely on a packing. A packing is information that specifies an arrangement of objects in a volume. An arrangement is a position(s), location(s), and/or orientation(s), etc., of an object or objects. An “object” may refer to a geometrical representation or 3D shape. A volume is a 3D space. A build volume is a volume that may be used for manufacturing. In some examples, a build volume may correspond to a physical space in which additive manufacturing may be performed. In some examples, a build volume may be structured as a 3-dimensional space bounded by a predefined polyhedron (e.g., a set of vertices, edges, and faces) that specify the packing space scope.

It may be helpful to increase packing density in the build volume to increase production and/or reduce manufacturing costs. In some examples, a build volume (e.g., packing space) may be a cuboidal space with x, y, and z dimensions. For example, a build volume may be a cuboid with dimensions of 284 millimeters (mm) in the x axis by 380 mm in the y axis by 380 mm in the z axis.

In some examples, object packing may be based on an objective or objectives. An example of an objective is packing density (e.g., increasing or maximizing packing density). Object packing questions may be computationally intensive to solve, being nondeterministic polynomial- (NP-) complete. For example, computational complexity may grow exponentially in NP-complete questions. For instance, the size of the solution space (e.g., amount of possible packing arrangements) for placement of objects (without rotation, for example) in a relatively small batch of 20 objects, is beyond the order of 1×10¹⁸. Some examples of the techniques described herein may provide practical and/or near-optimal approaches for object packing. For instance, some of the techniques described herein may enable searching over the solution space while prioritizing portions that have a greater probability of producing a near-optimal solution. In some examples, a relatively small portion of the solution space may be searched. Some of the techniques described herein may help to evaluate whether a sufficient solution space has been searched (e.g., has been searched before an amount of allocated computational time or generations is exhausted).

Throughout the drawings, identical reference numbers may or may not designate similar or identical elements. Similar numbers may or may not indicate similar elements. When an element is referred to without a reference number, this may refer to the element generally, with or without limitation to any particular drawing or figure. The drawings are not necessarily to scale, and the size of some parts may be exaggerated to more clearly illustrate the example shown. Moreover, the drawings provide examples in accordance with the description. However, the description is not limited to the examples provided in the drawings.

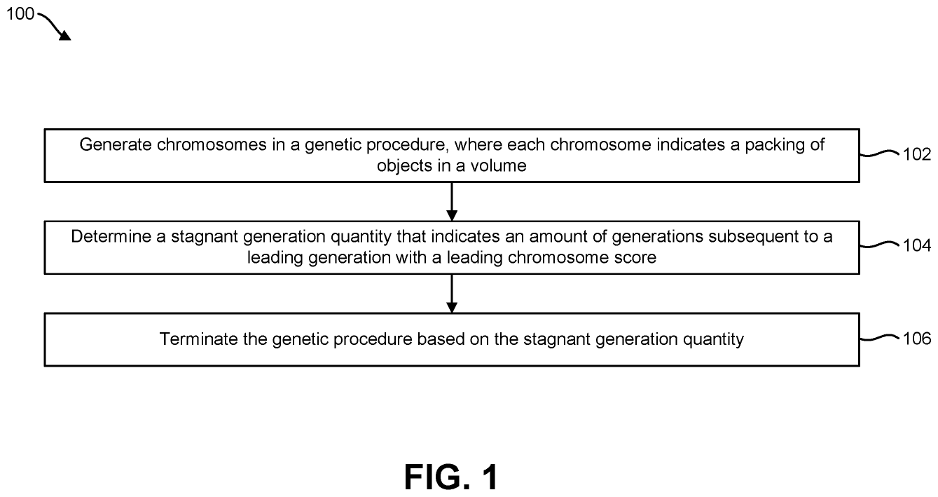

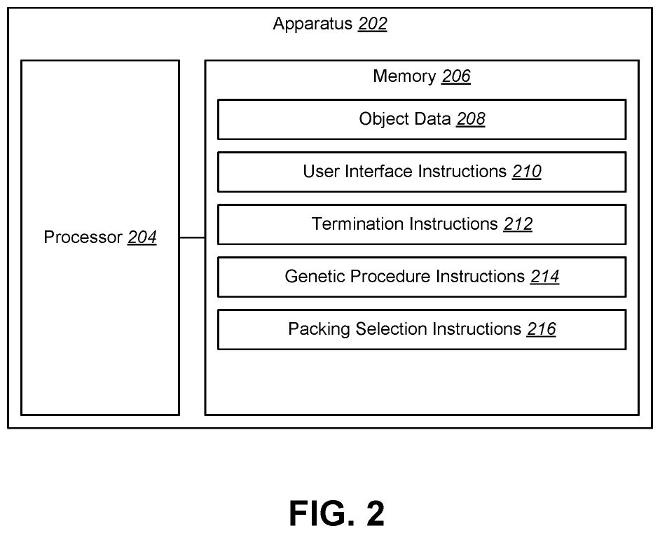

FIG. 1 is a flow diagram illustrating an example of a method 100 for object packing genetic procedures. The method 100 and/or a method 100 element or elements may be performed by an apparatus (e.g., electronic device). For example, the method 100 may be performed by the apparatus 202 described in relation to FIG. 2.

An apparatus may generate 102 chromosomes in a genetic procedure, where each chromosome indicates a packing of objects in a volume. A genetic procedure is a computational procedure. For example, a genetic procedure may be a metaheuristic procedure that includes evolution and/or selection mechanisms for determining a solution. In some examples, a genetic procedure may be a technique utilized in artificial intelligence. In some examples, the genetic procedure may include initializing a population, evaluation, selection, crossover, and/or mutation operations. In some examples, evaluation, selection, crossover, and/or mutation may be performed repeatedly (e.g., iteratively, recursively, etc.) until an end condition is met. In some examples, generating 102 chromosomes in a genetic procedure may be performed in initializing a population, evaluation, selection, crossover, and/or mutation operations. A population is a group or set of chromosomes.

A chromosome is data. For example, a chromosome may include data representing a potential solution for a question that the genetic procedure is to address. For instance, a chromosome may indicate a packing of objects in a volume (e.g., build volume). A packing is an organization of objects. For instance, chromosomes may indicate packing positions. A packing position is a pose of an object in a build volume. In some examples, a chromosome may include data indicating a set of object identifiers and poses. An object identifier is information (e.g., number, floating point number, integer, string, character(s), name, etc.) that identifies an object. A pose is information indicating a location and/or orientation of an object. For instance, a pose may indicate a location (e.g., translation) of an object in a build volume and/or an orientation (e.g., rotation(s) in a dimension or dimensions) of an object in a build volume. In some examples, a pose may be expressed as a number or numbers (e.g., floating point numbers, integers, etc.), vector(s), matrix or matrices, quaternion(s), etc. In some examples, a chromosome may include an object identifier with a first axis rotation (e.g., x), a second axis rotation (e.g., y), and a third axis rotation (e.g., z) for each of a set of objects. In some examples, a chromosome may include an object identifier with an orientation (and without location, for instance) for each of a set of objects. In some examples, each gene of a chromosome may include an object identifier and/or pose (e.g., orientation and/or location). For instance, a gene or genes of a chromosome may indicate and/or represent an object or objects.

In some examples, a chromosome may include data for each object in an order or sequence. In some examples, the order or sequence of a chromosome may correspond to a packing order in the volume (e.g., build volume). For instance, the apparatus may place the objects of a chromosome in the volume (e.g., build volume) in the order or sequence indicated in the chromosome. In some cases, consecutive objects in a chromosome may be placed adjacently in the volume if volume dimensions allow, to an extent that volume dimensions allow, and/or to an extent that previously-placed object(s) allow. In some examples, the order or sequence may establish a priority queue. For instance, the order or sequence may indicate an order that objects may be introduced into a build volume. In some examples, a chromosome may include an object identifier and rotations for respective objects from object 1 to object n. For instance, a chromosome may encode an object list, where each element of the list indicates an identifier of an object and/or rotation angles corresponding to axes (e.g., in x, y, and z axes). In some examples, the order or sequence of a chromosome may be an order or sequence of object identifiers. In some examples, each chromosome may represent a potential packing described as a sequence of object identifiers with associated poses.

In initializing a population, the apparatus may randomly initialize a set of chromosomes. For example, the apparatus may utilize a random number generator to generate random poses for a set of objects (to be packed in a build volume, for instance). In some examples, the initialized set of chromosomes may include sequences of object identifiers and poses.

In performing evaluation, the apparatus may evaluate and/or rank the chromosomes according to a value or values. Examples of values include fitness measures. A fitness measure is a measure that indicates a degree to which a chromosome (e.g., packing) satisfies an objective or objectives (e.g., increased quantity of objects packed, increased packing density, decreased packing height, and/or decreased z-axis measure, etc.). For example, the fitness measure may be evaluated for each chromosome (e.g., packing). Examples of fitness measures may include quantity of objects packed, packing density, packing height (e.g., z-height), quantity of unpacked objects (e.g., objects that did not fit in the packing), and/or re-radiation score, etc.

A quantity of objects packed is a quantity of objects that fit within the volume (e.g., build volume) for a chromosome. A quantity of objects packed may be determined for each chromosome. A fitness score is a value or values (e.g., fitness measure(s)) that indicates a characteristic of a chromosome and/or packing. For example, a fitness score may be a quantity of objects packed, packing density, packing height, etc., or any combination (e.g., sum, average, weighted average, vector, etc.) thereof. Quantity of objects packed is a value indicating a quantity or amount of objects in a chromosome and/or packing. Packing density is a value that indicates a degree to which an object or objects occupy a space (e.g., volume). For instance, a packing density may be determined as a percentage of volume that is occupied, a ratio of occupied volume to total volume (e.g., a percentage of occupied voxels to total voxels in a volume), and/or a ratio of occupied volume to unoccupied volume, etc. Packing height is a value that indicates a distance along a dimension (e.g., height dimension, z dimension, etc.). For instance, a packing height may be determined as a distance (e.g., difference) between a lowest height value and a highest height value of objects in a chromosome and/or packing. Quantity of unpacked objects is a value or quantity of objects that do not fit in a volume. For instance, the quantity of unpacked objects may be a quantity of input objects that do not fit in a volume in accordance with a chromosome and/or packing. A re-radiation score is a quantity or value that indicates an amount of re-radiation. Re-radiation is a value or quantity indicating a physical phenomenon that may occur when material (e.g., a layer) is exposed to energy or heat (e.g., lamp lights), and some of the rays may recursively bump from a material surface to an energy source (e.g., lamp carriage), which may occur in a build volume while printing layer to layer. A higher re-radiation score may indicate a higher probability of objects being overheated (e.g., “overcooked”).

In some examples, a value or values (e.g., fitness measure, quantity of objects packed, packing density, packing height, quantity of unpacked objects, etc.) may be utilized to rank or order chromosomes. In some examples, a group of values (e.g., fitness measure, quantity of objects packed, packing density, and/or packing height, etc.) may be assembled and/or combined to form a packing score that can be utilized to rank one packing over another packing. For instance, a packing score may be determined based on a function, combination, mapping, weighted sum, average, etc., of multiple values (e.g., fitness measure, quantity of objects packed, packing density, and/or packing height, etc.). In some examples, chromosomes with a relatively greater packing density, a relatively greater quantity of objects packed, and/or a relatively lesser packing height may be ranked higher than other chromosomes.

In some examples, the value(s) (e.g., fitness measure(s), packed quantity(ies), packing density(ies), and/or packing height(s), etc.) may be determined based on a placement procedure. An example of a placement procedure is a bottom-front-left placement procedure. For instance, the objects of a chromosome may be placed in the volume (e.g., build volume) in accordance with the placement procedure to produce a packing. The value(s) (e.g., fitness measure(s), packed quantity(ies), packing density(ies), and/or packing height(s), etc.) may be determined (e.g., calculated, computed, etc.) based on the packing.

In some examples, a bottom-front-left placement procedure may utilize the object sequence of a chromosome to enter each object in sequence (e.g., one after another in the given order). The bottom-front-left placement procedure (e.g., heuristic) may enter an object from a top-back-right corner of a build volume, and move (e.g., incrementally move, continuously move, etc.) the object downward (e.g., along a z axis) until contacting or colliding with another object or contacting or colliding with a build volume frontier (e.g., edge, boundary, etc.). The object may then be moved from a back of the build volume frontward (e.g., along a y axis) until contacting or colliding with another object or contacting or colliding with a build volume frontier. The object may then be moved from a right side of the build volume leftward (e.g., along an x axis) until contacting or colliding with another object or contacting or colliding with a build volume frontier. In some examples, a margin or spacing (0.01 millimeters (mm), 0.1 mm, 1 mm, 3 mm, etc., from a colliding or contacting position, for instance) may be inserted and/or utilized between object placements. Other placement procedures may be utilized in some examples. For instance, other placement procedures that place the objects of the chromosome(s) in different orders and/or proceeding in different directions may be utilized in some examples.

In performing selection, the apparatus may eliminate a quantity of the chromosomes. For instance, the apparatus may eliminate (e.g., discard, delete, remove, exclude, etc.) a quantity of the lowest ranked chromosomes (e.g., a percentage of lowest ranked chromosomes, a quantity of lowest ranked chromosomes, etc.). In some examples, the chromosomes may be categorized based on rank. For example, a first quantity of the chromosomes (e.g., percentage of chromosomes, amount of chromosomes, etc.) may be categorized in a first category. For instance, the first quantity may be a set of highest ranked chromosomes. The first quantity of chromosomes may be referred to as elite chromosomes (e.g., a quantity of chromosomes with best fitness measures, quantities of objects packed, packing height, and/or packing density, etc.). In some examples, a gene or genes (e.g., object identifier(s) and/or pose(s)) of the elite chromosomes may be preserved and/or propagated to a subsequent (e.g., next) generation of chromosomes. A generation is a set of chromosomes (e.g., packings). For example, a generation may correspond to each iteration of the genetic procedure.

In some examples, selection may include chromosome selection for propagation (e.g., mutation and/or crossover) and/or packing (e.g., selecting a chromosome for a packing solution). For instance, the apparatus may select a chromosome or chromosomes based on a rank that is based on fitness scores, quantities of objects packed, packing density, and/or packing height, etc.

In some examples, selecting a chromosome may be based on a value or values. In some examples, selecting a chromosome for propagation is based on a fitness score. For example, a chromosome or chromosomes with better (e.g., a set of top) fitness scores may be selected for propagation and/or packing. For instance, selecting a chromosome for propagation may be based on a quantity of objects packed. For instance, chromosomes with higher quantities of objects packed, higher packing density, and/or lower packing height may be selected for propagation and/or packing. As used herein, the term “better” may mean that one value indicates superiority to another value in terms of an objective or objective. For instance, a “better” value may be greater than another value in some examples, or a “better” value may be less than another value in some examples. For example, a better value for a packing density may be a greater packing density relative to another packing density. In another example, a better value for a packing height may be a lesser packing height relative to another packing density. Some “better” values may depend on multiple values. For instance, a vector may be compared with another vector, where individual vector elements may be compared, or a value (e.g., weighted sum, average, etc.) may include multiple factors for comparison.

In performing crossover, the apparatus may utilize a second quantity of chromosomes and elite chromosomes. The second quantity of the chromosomes may be referred to as crossover chromosomes. The second quantity of chromosomes may be ranked below the elite chromosomes. For instance, the apparatus may randomly select chromosomes that are ranked below the elite chromosomes to select the crossover chromosomes. The apparatus may crossover the crossover chromosomes with the elite chromosomes. For example, the apparatus may combine a part or parts (e.g., gene(s), object identifier(s), pose(s), location(s), orientation(s), rotation(s), and/or sequence position(s)) of an elite chromosome with a part or parts (e.g., gene(s), object identifier(s), pose(s), location(s), orientation(s), rotation(s), and/or sequence position(s)) of a crossover chromosome to generate a child chromosome in a subsequent (e.g., next) generation of chromosomes.

In performing mutation, the apparatus may randomly mutate an elite chromosome or elite chromosomes. For example, the apparatus may randomly change a gene or genes (e.g., object identifier(s), pose(s), location(s), orientation(s), rotation(s), and/or sequence position(s)) of an elite chromosome or elite chromosomes. The chromosomes to be mutated may be referred to as mutation chromosomes.

In some examples, a constant population size (e.g., amount of chromosomes) may be maintained over generations. In some examples, the population size may vary over generations. In some examples, new random chromosomes may be added. For instance, a set of randomly generated chromosomes may be added to the elite chromosomes, crossover chromosomes, and mutation chromosomes. For instance, adding new random chromosomes may maintain the constant population size. The random chromosomes may be useful for driving a random search in different directions in the solution space. In some approaches, mutations of chromosomes may be represented as random movements in the object sequence and/or random rotations on the object orientations. The mutation stage may be utilized to mutate elite chromosomes (e.g., good solutions) into chromosomes with increased fitness (e.g., better solutions). Performing selection, crossover, and/or mutation may produce a subsequent generation of chromosomes.

In some examples, each subsequent generation of chromosomes may be equal to or better than a previous generation (e.g., ancestor(s)) due to the elite chromosomes. In some examples, the packing procedure may monotonically increase packing quality from generation to generation until an end condition occurs (e.g., a maximum generation threshold is reached). When an end condition occurs, the genetic procedure may terminate and provide a current leading chromosome, packing, and/or solution. A leading chromosome is a chromosome with a leading chromosome score. A chromosome score is a value or values (e.g., fitness measure, quantity of objects packed, packing density, packing height, etc.) indicating a degree of quality of a chromosome and/or of a corresponding packing. A leading chromosome score is a best or leading (e.g., maximum, minimum, top, and/or highest, etc.) value or values (e.g., fitness measure, quantity of objects packed, packing density, packing height, etc.) out of a set of values corresponding to a set of chromosomes and/or packings. A leading generation is a generation with a leading chromosome score and/or leading chromosome. In some examples, a leading generation is an earliest or first generation in which a leading chromosome score was achieved. For instance, if a leading chromosome score was first achieved in an 8th generation, and a subsequent generation or generations (e.g., 9th, 10th, 11th generations, etc.) achieve a matching chromosome score, but do not achieve a better chromosome score, the 8th generation may be the leading generation.

In some examples, an operation or operations of the genetic procedure may repeat (e.g., iterate, recur, etc.). For example, evaluation, crossover, and/or mutation may be repeated for subsequent generations of chromosomes until an end condition is met (e.g., a maximum threshold amount of generations, a threshold quantity of packed objects, a threshold fitness score, and/or a threshold packing score, etc.). For example, an apparatus may generate 102 chromosomes by iterating the genetic procedure over a generation or generations.

The apparatus may determine 104 a stagnant generation quantity that indicates an amount of generations subsequent to a leading generation with a leading chromosome score. A stagnant generation quantity is an indicator (e.g., amount, quantity, number, integer, code, etc.) of an amount of generations since a leading generation. For instance, a stagnant generation quantity may be counted from a generation in which a leading chromosome score was first determined and/or achieved. In some examples, the apparatus may maintain a count for generations and/or iterations in which a better chromosome score is not achieved. A stagnant generation may be a generation with a best packing result (e.g., chromosome score) that is not better than the leading packing result (e.g., leading chromosome score). For instance, a stagnant generation quantity may be an amount of stagnant generations since the leading generation where the leading best packing result was found. In some examples, the apparatus may compare a current chromosome score (e.g., a best chromosome score of a current generation) with the leading chromosome score and increment the stagnant generation quantity in response to determining that the current chromosome score is not better (e.g., greater than the leading chromosome score).

In some examples, determining 104 the stagnant generation quantity may include determining whether a current chromosome score (e.g., a best chromosome score of a current generation or most recent generation) is better than the leading chromosome score. In an example, the apparatus may determine if the greatest packing density of the current generation is greater than the greatest packing density of the leading generation. In another example, the apparatus may determine if the smallest packing height of the current generation is less than the smallest packing density of the leading generation. In a case that the current chromosome score (e.g., packing density, packing height, quantity of objects packed, and/or fitness score, etc.) is better than the leading chromosome score, the apparatus may reset the stagnant generation quantity and set the leading chromosome score to the current chromosome score. For instance, the stagnant generation quantity may be reset to 0 (e.g., Q_{S}=0, where Q_{S} is the stagnant generation quantity) and the current chromosome score may become the leading chromosome score (and/or the current generation may become the leading generation). In a case that the current chromosome score is not better than the leading chromosome score, the apparatus may increment the stagnant generation quantity. For instance, Q_{S}=Q_{S}+1.

The apparatus may terminate 106 the genetic procedure based on the stagnant generation quantity. For example, the stagnant generation quantity may be utilized to determine whether to terminate the genetic procedure. For instance, the stagnant generation quantity may be utilized to determine whether a condition or conditions (e.g., end condition(s)) is or are satisfied to terminate the genetic procedure. Examples of a condition may include a stagnant generation threshold, a packed quantity threshold, a fitness score threshold, a packing height threshold, and/or a packing density threshold, etc. A condition or a set of conditions may be utilized to determine whether to terminate the genetic procedure.

In some examples, the method 100 may include comparing the stagnant generation quantity to a stagnant generation threshold. A stagnant generation threshold is a threshold to satisfy a condition using a stagnant generation quantity. For instance, the apparatus may compare the stagnant generation quantity to the stagnant generation threshold. In a case that the stagnant generation threshold is satisfied (e.g., if the stagnant generation quantity is greater than or at least the stagnant generation threshold), the apparatus may terminate 106 the genetic procedure in some examples. Examples of the stagnant generation threshold may include 10, 20, 35, 50, 64, 100, etc.

In some examples, terminating 106 the genetic procedure may be based on a set of conditions that includes a stagnant generation threshold. For instance, the stagnant generation threshold may be one of the set of conditions. In some examples, the set of conditions may be a logic rule. A logic rule is a rule that is satisfied when a condition or conditions of the logic rule is or are satisfied. For instance, the logic rule may include conditions combined with a logical operator or operators (e.g., “and” and/or “or” operators). In some examples, the set of conditions (and/or logic rule) may be a Boolean function.

In some examples, the apparatus may determine a value or values (e.g., quantity(ies) of packed objects, fitness score(s), packing height(s), and/or packing density(ies), etc.) corresponding to chromosome(s) and/or packing(s) for each iteration and/or generation of the genetic procedure. For instance, the value(s) may be determined during evaluation. The value(s) may be determined during the genetic procedure and/or while the genetic procedure is being executed. The value(s) may be used to determine whether to terminate the genetic procedure in some examples. For example, the value(s) may be utilized with the set of conditions to determine whether to terminate the genetic procedure.

In some examples, the set of conditions may include a packed quantity threshold. A packed quantity threshold is a threshold to satisfy a condition using a quantity of packed objects. For instance, the apparatus may compare a quantity of packed objects (corresponding to a chromosome and/or packing, for instance) to the packed quantity threshold. In a case that the packed quantity threshold is satisfied (e.g., if the quantity of packed objects is greater than or at least the packed quantity threshold), the apparatus may terminate 106 the genetic procedure in some examples. Examples of the packed quantity threshold may include 10, 20, 35, 50, 64, 70, 100, 230, etc.

In some examples, the set of conditions may include a fitness score threshold. A fitness score threshold is a threshold to satisfy a condition using a fitness score. For instance, the apparatus may compare a fitness score (corresponding to a chromosome and/or packing, for instance) to the fitness score threshold. In a case that the fitness score threshold is satisfied (e.g., if the fitness score meets the fitness score threshold), the apparatus may terminate 106 the genetic procedure in some examples. Examples of the fitness score threshold may include 8, 9.5, 10.2, 11, etc.

In some examples, the set of conditions may include a packing height threshold. A packing height threshold is a threshold to satisfy a condition using a packing height. For instance, the apparatus may compare a packing height (corresponding to a chromosome and/or packing, for instance) to the packing height threshold. In a case that the packing height threshold is satisfied (e.g., if the packing height is less than or not more than the packing height threshold), the apparatus may terminate 106 the genetic procedure in some examples. Examples of the packing height threshold (in mm, for instance) may include 250, 275, 300, 310, etc.

In some examples, the set of conditions may include a packing density threshold. A packing density threshold is a threshold to satisfy a condition using a packing density. For instance, the apparatus may compare a packing density (corresponding to a chromosome and/or packing, for instance) to the packing density threshold. In a case that the packing density threshold is satisfied (e.g., if the packing density is greater than or not less than the packing density threshold), the apparatus may terminate 106 the genetic procedure in some examples. Examples of the packing density threshold may include 8, 9.5, 10.2, 11, etc.

Examples of sets of conditions (e.g., end conditions), logic rules, and/or Boolean functions are given as follows. In some examples, terminate_criterion=quantity_of_packed_objects≥70 and fitness_score≥10.2, where terminate_criterion is a criterion and/or indicator of whether to terminate the genetic procedure, quantity_of_packed_objects is a quantity of packed objects of a chromosome and/or packing, and fitness_score is a fitness score of a chromosome and/or packing. In this example, the set of conditions includes obtaining 70 or more packed objects with a fitness score that is greater than or not less than 10.2%. In some examples, the fitness score may be a ratio given by a sum of packed object volumes divided by build volume (e.g., packing space). Higher fitness scores (e.g., packing densities) may indicate denser packings. Depending on the geometry of the objects to be packed, a fitness score may vary from 0 to 100 in some examples. In some cases, fitness scores may range approximately from 5 to 20%. In some examples, a packing height (e.g., z-height) condition may be utilized. For example, terminate_criterion=quantity_of_packed_objects≥70 or (fitness_score≥10.2 and packing_height≤300), where packing_height is a packing height of a chromosome and/or packing. In this example, the set of conditions includes obtaining a chromosome and/or packing with 70 or more packed objects, or a chromosome and/or packing with a fitness score greater than or not less than 10.2 and a packing height less than or not more than 300 mm (regardless of a quantity of objects packed), whatever happens first. In some examples, the set of conditions may not utilize and/or include a stagnant generation quantity and/or stagnant generation threshold.

In some examples, the stagnant generation quantity may be included in the set of conditions. For instance, termination_criterion=quantity_of_packed_objects≥70 or fitness_score≥10.2 or stagnant_generations≥50, wherein stagnant_generations is a stagnant generation quantity and 50 is an example of a stagnant generation threshold. In this example, the set of conditions includes obtaining a chromosome and/or packing with 70 or more objects packed, or a chromosome and/or packing with a fitness score greater than or not less than 10.2, or where the genetic procedure has not bettered a leading chromosome and/or packing solution for 50 stagnant generations (e.g., the stagnant generations are greater than or not less than 50). This example may target reaching 70 objects packed or reaching 10.2% of packing density, while avoiding unending execution by bounding the amount of stagnant generations to 50.

In some examples, the condition or set of conditions may be established with packing parameters (e.g., population size, amount of generations, etc.). In some examples, the condition or set of conditions may be established and/or modified based on received user input (before and/or during the genetic procedure execution).

In some examples, the condition or set of conditions may be evaluated for each genetic procedure generation after ranking chromosomes and/or performing packing procedures for the chromosomes in the population. If a chromosome with the best value(s) (e.g., best fitness score, packing height, packing density, and/or quantity of objects packed) satisfies the condition or set of conditions (e.g., end condition(s)), then the chromosome may be selected and/or reported as the final result of the genetic procedure.

In some examples, the condition or set of conditions (e.g., end condition(s)) may be an open end condition. An open end condition is an end condition where genetic procedure execution continues until the condition is satisfied or until the genetic procedure is terminated based on a received user input (e.g., an input from an interactive interface). In some examples, the condition or set of conditions (e.g., end condition(s)) may be a closed end condition. A closed end condition is an end condition where genetic procedure execution terminates when the condition is satisfied or when a maximum generation threshold is reached. A maximum generation threshold is a threshold to limit iteration of the genetic procedure. For instance, iterations or generations of a genetic procedure may be limited to the maximum generation threshold. In some examples, the value(s) (e.g., quantity(ies) of packed objects, packing height(s), packing density(ies), and/or fitness score(s)) and/or the stagnant generation quantity (and stagnant generation threshold, for instance) may be used to determine whether to terminate the genetic procedure before a maximum generation threshold is reached.

In some examples, the maximum generation threshold may limit the genetic procedure. In some cases, the genetic procedure may determine good results (e.g., a good chromosome and/or packing) within the maximum generation threshold (e.g., within a time range of the maximum generation threshold). Genetic procedure convergence may depend on multiple factors (e.g., object geometries and/or packing parameters such as population size, amount of elite chromosomes, random seed, etc.).

In some examples of the techniques described herein, a condition or set of conditions may be utilized to track genetic procedure performance and automatically terminate the genetic procedure when the condition or set of conditions is met. In some examples, the condition of set of conditions may be utilized with a maximum generation threshold. Accordingly, the genetic procedure may terminate before or at the maximum generation threshold. Terminating before the maximum generation threshold is met may reduce and/or conserve computational resources. In some examples, the condition or set of conditions may be a Boolean function of a quantity of packed objects, fitness score, packed height, and/or stagnant generation quantity. In some cases, as the stagnant generation quantity increases, the probability of finding a better chromosome and/or packing may decrease.

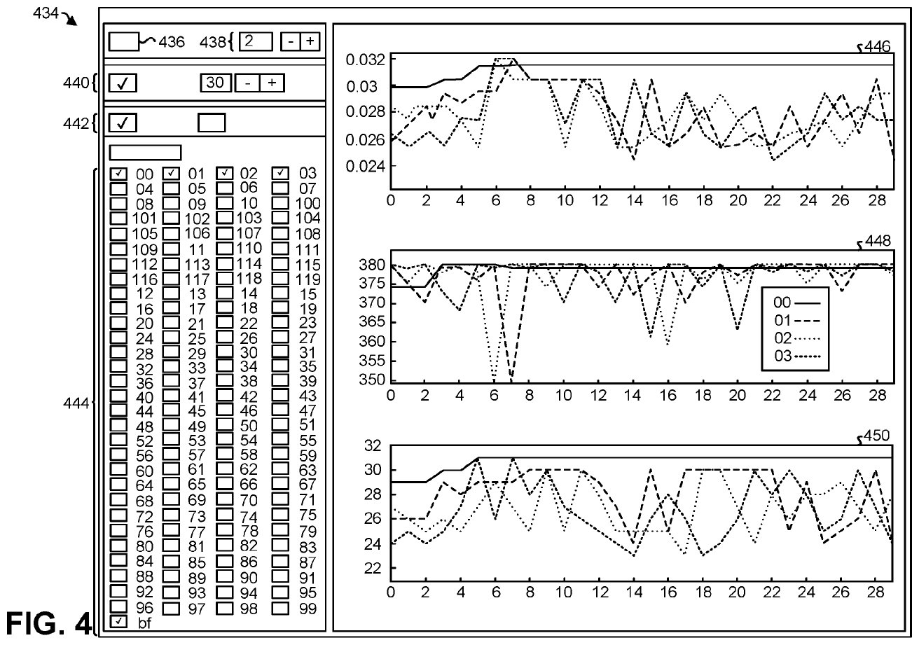

In some examples, the method 100 may include producing a user interface to display a tracked value or values of the chromosomes. In some examples, the user interface may include a stop control and a plot of the tracked value or values. For instance, the apparatus may receive an input (e.g., mouse click, keyboard input, tap on a touchscreen, etc.) corresponding to the stop control. In a case that an input corresponding to the stop control is received, the apparatus may terminate the genetic procedure. An example of a user interface is described in relation to FIG. 4.

In some examples, the method 100 may include selecting a packing based on the chromosomes (e.g., chromosomes after a generation or generations). In some examples, selecting the packing is based on the genetic procedure with an objective. For instance, the apparatus may select a chromosome that represents a packing with a highest ranking, best value(s), best packing score, maximum quantity of packed objects, best fitness score, maximum packing density, and/or minimum height, etc. In some examples, the apparatus may select the packing based on an objective (e.g., packing density, quantity of packed objects, packing height, and/or fitness, etc.) or a combination of objectives. For instance, a packing with a best combination of objectives, such as quantity of packed objects, packing density, packing height, and/or fitness score, may be selected.

In some examples, the packing may be executed to manufacture the objects. For example, the objects may be manufactured by an apparatus (e.g., 3D printer) in accordance with the selected packing. For instance, an apparatus may send the packing to another device (e.g., 3D printer) or may execute the packing to manufacture the objects in the packing. Some examples of the techniques described herein may be utilized in a variety of additive manufacturing. Some additive manufacturing techniques may be powder-based and driven by powder fusion. Some additive manufacturing techniques may include metal printing, such as metal jet fusion. Some examples of the approaches described herein may be utilized in powder bed fusion-based additive manufacturing, such as Selective Laser Melting (SLM), Selective Laser Sintering (SLS), Multi-Jet Fusion (MJF), etc.

In some examples, the method 100 may include presenting the selected packing. For instance, the apparatus may send an image of the packing to a display for presentation. In some examples, the method 100 may include sending the selected packing to another device (e.g., computing device, server, etc.). For instance, the apparatus may transmit the selected packing to another device via a network (e.g., a local area network, the Internet, etc.).

FIG. 2 is a block diagram of an example of an apparatus 202 that may be used in object packing genetic procedures. The apparatus 202 may be an electronic device, such as a personal computer, a server computer, a printer, a 3D printer, a smartphone, a tablet computer, etc. The apparatus 202 may include and/or may be coupled to a processor 204 and/or a memory 206. In some examples, the apparatus 202 may be in communication with (e.g., coupled to, have a communication link with) an additive manufacturing device (e.g., a 3D printing device). In some examples, the apparatus 202 may be an example of a 3D printing device. The apparatus 202 may include additional components (not shown) and/or some of the components described herein may be removed and/or modified without departing from the scope of the techniques described herein.

The processor 204 may be any of a central processing unit (CPU), a semiconductor-based microprocessor, graphics processing unit (GPU), field-programmable gate array (FPGA), an application-specific integrated circuit (ASIC), and/or other hardware device suitable for retrieval and execution of instructions stored in the memory 206. The processor 204 may fetch, decode, and/or execute instructions (e.g., termination instructions 212, user interface instructions 210, genetic procedure instructions 214, and/or packing selection instructions 216) stored in the memory 206. In some examples, the processor 204 may include an electronic circuit or circuits that include electronic components for performing a function or functions of the instructions (e.g., termination instructions 212, user interface instructions 210, genetic procedure instructions 214, and/or packing selection instructions 216). In some examples, the processor 204 may perform one, some, or all of the functions, operations, elements, methods, etc., described in relation to one, some, or all of FIGS. 1-4.

The memory 206 may be any electronic, magnetic, optical, or other physical storage device that contains or stores electronic information (e.g., executable instructions, executable code, and/or data). The memory 206 may be, for example, Random Access Memory (RAM), Electrically Erasable Programmable Read-Only Memory (EEPROM), a storage device, an optical disc, and the like. In some examples, the memory 206 may be volatile and/or non-volatile memory, such as Dynamic Random Access Memory (DRAM), EEPROM, magnetoresistive random-access memory (MRAM), phase change RAM (PCRAM), memristor, flash memory, and the like. In some examples, the memory 206 may be a non-transitory tangible machine-readable storage medium, where the term “non-transitory” does not encompass transitory propagating signals. In some examples, the memory 206 may include multiple devices (e.g., a RAM card and a solid-state drive (SSD)).

In some examples, the apparatus 202 may include an input/output interface (not shown in FIG. 2) through which the processor 204 may communicate with an external device or devices (not shown), for instance, to receive and store information (e.g., object data 208) pertaining to an object or objects to be manufactured (e.g., printed). The input/output interface may include hardware and/or machine-readable instructions to enable the processor 204 to communicate with the external device or devices. The input/output interface may enable a wired and/or wireless connection(s) to the external device or devices. The input/output interface may further include a network interface card and/or may also include hardware and/or machine-readable instructions to enable the processor 204 to communicate with various input and/or output devices, such as a keyboard, a mouse, a display, a touch screen, another apparatus, electronic device, computing device, etc., through which a user may input instructions into the apparatus 202. For example, the apparatus or another device may receive an input (e.g., keyboard input, touchscreen input, mouse input, wireless signal, and/or stylus input, etc.).

In some examples, the memory 206 may store object data 208. The object data 208 may be obtained (e.g., received) from an external device and/or may be generated on the apparatus 202. For example, the processor 204 may execute instructions (not shown in FIG. 2) to receive the object data 208 from an external device and/or to generate the object data 208.

The object data 208 may include data indicating objects and/or shapes (e.g., 3D models, dimensions, etc.) of objects. For example, the object data 208 may indicate objects for packing and/or manufacture.

In some examples, the processor 204 may execute the genetic procedure instructions 214 to iterate a genetic procedure to generate chromosomes representing packings. In some examples, iterating the genetic procedure may be performed as described in relation to FIG. 1. In some examples, the processor 204 may initialize chromosome(s) representing packings. For example, the processor 204 may determine initial random chromosomes and/or randomizing the chromosomes and/or a portion of the chromosomes. For instance, the processor 204 may randomize object pose (e.g., location and/or orientation) information for objects in the chromosomes. In some examples, a chromosome may include a sequence of object identifiers with corresponding orientations.

In some examples, the processor 204 may execute the genetic procedure instructions 214 to iterate the genetic procedure. For instance, the processor 204 may perform evaluation, selection, crossover, and/or mutation on the chromosome(s). Performing initialization, evaluation, selection, crossover, and/or mutation may be performed as described in relation to FIG. 1 in some examples.

In some examples, the processor 204 may execute the genetic procedure instructions 214 to propagate a chromosome or chromosomes in a case that the evaluation is satisfied. In some examples, propagating the chromosome(s) in a case that the evaluation is satisfied may be performed as described in relation to FIG. 1. For example, the processor 204 may propagate (e.g., mutate and/or crossover) a chromosome or chromosomes that are above a ranking threshold. The apparatus 202 (e.g., processor 204) may iterate evaluating and propagating chromosomes for a generation or generations in some approaches.

In some examples, the processor 204 may execute the user interface instructions 210 to produce a user interface to display a tracked value (or values) of the chromosomes. For instance, the processor 204 may render a user interface (e.g., window(s), panel(s), interactive control(s), text, image(s), etc.) that indicates (e.g., illustrates, plots, etc.) a value or values of the chromosomes. Examples of values that may be rendered and/or displayed may include fitness measure(s), fitness score(s), quantity of packed objects, packing height, packing density, etc. The value(s) may be tracked, rendered, plotted, and/or displayed relative to a generation or generations. In some examples, the apparatus 202 may include a display(s) (e.g., touchscreen(s), display panel(s), etc.) and/or may be linked to a display(s) (e.g., monitor(s), display panel(s), etc.). The apparatus 202 may present and/or display the user interface on the display(s).

In some examples, the user interface includes a plot of the tracked value(s). For instance, the user interface may include a plot or plots (e.g., graph(s)) of the value(s). In some examples, the value(s) may be plotted over a generation or generations. The plot may be updated as the genetic procedure progresses.

In some examples, the user interface includes a stop control. The stop control is an interactive control that enables receiving an input to stop and/or terminate the genetic procedure. For instance, the stop control may be a button, region, toggle control, radio button, and/or text, etc. In some cases, the apparatus 202 may receive a stop input associated with the stop control. A stop input is an input indicating a directive to stop or terminate the genetic procedure. For instance, the apparatus 202 may receive a mouse click when a cursor is on the stop control or may detect a tap on a touch screen on the stop control. In some examples, the user interface may include a stop control and a plot of the tracked value(s).

In some examples, the processor 204 may execute the termination instructions 212 to determine whether to terminate the genetic procedure based on a stagnant generation quantity and whether a stop input from the user interface is detected. For instance, the processor 204 may determine a stagnant generation quantity of the genetic procedure as described in relation to FIG. 1. The processor 204 may utilize the stagnant generation quantity and/or whether a stop input is detected to determine whether to terminate the genetic procedure. For instance, the processor 204 may determine to terminate the genetic procedure if a stop input is detected or if the stagnant generation quantity is greater than or not less than a stagnant generation threshold. In some examples, the processor 204 may execute the termination instructions 212 to determine whether to terminate the genetic procedure based on a condition or set of conditions as described in relation to FIG. 1. For instance, determining whether to terminate the genetic procedure may be based on a fitness score, a fitness score threshold, a packing density, a packing density threshold, a packing height, a packing height threshold, a quantity of packed objects, a packed quantity threshold, a stagnation generation quantity, and stagnation generation threshold, whether a stop input is detected, a quantity of generations (e.g., total generations, all generations and/or iterations performed by the genetic procedure for the objects), and/or a maximum generation threshold, etc.

In some examples, the user interface includes a query interval control, a generation range control, and/or a chromosome identifier selection control. The query interval control is a control to set and/or modify a query interval. A query interval is an interval or frequency in which genetic procedure results (e.g., a value or values of the genetic procedure) are retrieved for plotting on the user interface. The query interval may be expressed in terms of time (e.g., seconds (s)) and/or generations. A query interval control may include a text box(es), radio button(s), text, button(s), check box(es), and/or a list, etc.

A generation range control is a control to set and/or modify a generation range. A generation range is a quantity of generations (e.g., values of generations) to plot and/or display on the user interface. A generation range control may include a text box(es), radio button(s), text, button(s), check box(es), and/or a list, etc.

A chromosome identifier selection control is a control to select a chromosome or chromosomes for which a value or values are to be plotted and/or displayed on the user interface. A chromosome identifier selection control may include a text box(es), radio button(s), text, button(s), check box(es), and/or a list, etc. An example of the user interface is described in relation to FIG. 4.

In some examples, the processor 204 may execute the packing selection instructions 216 to select a packing based on the chromosome(s). For example, the processor 204 may select a chromosome as a packing with a maximum quantity of packed objects, best fitness measure, highest packing density, smallest packing height, and/or best packing score from the chromosomes (e.g., packings based on the chromosomes). In some examples, the apparatus 202 may perform manufacturing based on the selected packing. For example, the apparatus 202 may 3D print the selected packing and/or send the selected packing to a 3D printer for manufacture.

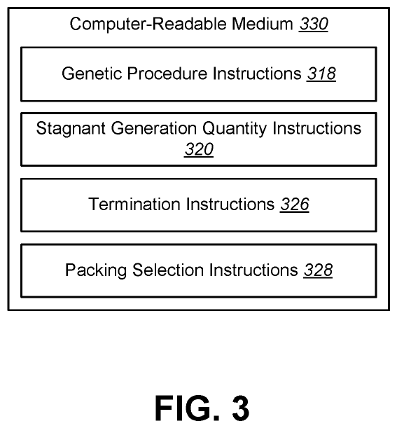

FIG. 3 is a block diagram illustrating an example of a computer-readable medium 330 for object packing genetic procedures. The computer-readable medium is a non-transitory, tangible computer-readable medium 330. The computer-readable medium 330 may be, for example, RAM, EEPROM, a storage device, an optical disc, and the like. In some examples, the computer-readable medium 330 may be volatile and/or non-volatile memory, such as DRAM, EEPROM, MRAM, PCRAM, memristor, flash memory, and the like. In some examples, the memory 206 described in relation to FIG. 2 may be an example of the computer-readable medium 330 described in relation to FIG. 3.

The computer-readable medium 330 may include code (e.g., data and/or instructions). For example, the computer-readable medium 330 may include genetic procedure instructions 318, stagnant generation quantity instructions 320, termination instructions 326, and/or packing selection instructions 328.

In some examples, the genetic procedure instructions 318 are code to cause a processor to produce a current generation of chromosomes using a genetic procedure. For instance, the genetic procedure instructions 318 may be instructions to cause a processor to initialize chromosomes, evaluate chromosomes, generate chromosomes, crossover chromosomes, and/or mutate chromosomes. For example, the genetic procedure may randomly initialize orientations of objects in chromosomes, evaluate the chromosomes, crossover the chromosomes, and/or mutate the chromosomes to produce a generation or generations of chromosomes. A current generation of chromosomes may be a last or most recently produced generation of chromosomes. In some examples, the genetic procedure may be used to produce a current generation of chromosomes as described in relation to FIG. 1 and/or FIG. 2.

In some examples, the genetic procedure instructions 318 may be code to cause the processor to determine a current set of chromosome scores based on the current generation of chromosome. A chromosome score is an indicator of a quality or characteristic of a chromosome. Examples of chromosome scores may include values, fitness measures, fitness scores, quantities of packed objects, packing heights, and/or packing densities, etc. For instance, the genetic procedure instructions 318 may include code to cause the processor to perform evaluation for each generation of chromosomes to produce the chromosome scores. The current set of chromosome scores may be a set of scores corresponding (e.g., respectively corresponding) to the chromosomes of the current generation.

In some examples, the stagnant generation quantity instructions 320 may include code to cause the processor to determine a stagnant generation quantity based on a comparison of a current best chromosome score to a previous leading chromosome score. For instance, the processor may compare the current best (e.g., maximum or minimum) chromosome score to a previous leading chromosome score. The previous leading chromosome score is a best chromosome score from a previous (e.g., leading) generation. In some examples, determining the stagnant generation quantity may be performed as described in relation to FIG. 1 and/or FIG. 2. For instance, if the current best chromosome score from the current generation is the same or less than the previous leading chromosome score, the stagnant generation quantity may be incremented and/or increased. If the current best chromosome score is better than the previous leading chromosome score, the stagnant generation quantity may be reset (e.g., reset to 0).

The termination instructions 326 may include code to cause the processor to determine whether to terminate the genetic procedure based on the stagnant generation quantity. In some examples, determining whether to terminate the genetic procedure may be accomplished as described in relation to FIG. 1 and/or FIG. 2. For instance, the termination instructions 326 may include code to cause the processor to execute the genetic procedure until a logic rule is satisfied. In some examples, the logic rule may include a packed quantity threshold, a fitness score threshold, and a stagnant generation threshold. The logic rule may be determined and/or executed by comparing values and/or indicators (e.g., quantity of packed objects, fitness scores, stagnant generation quantity, etc.) to corresponding thresholds. In some examples, the logic rule may include fewer, more, and/or different factors. For instance, a logic rule may include packed quantity threshold, a fitness score threshold, a packing density threshold, a packing height threshold, a stagnant generation quantity threshold, a maximum generation threshold, and/or another threshold(s) (e.g., packing score threshold(s)). If the logic rule is satisfied, the termination instructions 326 may be executed to terminate the genetic procedure. If the logic rule is not satisfied, the genetic procedure may continue (e.g., iterate).

In some examples, the packing selection instructions 328 are code to cause the processor to select a packing. For instance, a packing may be selected from a set of packings based on values, fitness scores, quantities of packed objects, packing densities, and/or packing heights. In some examples, selecting the packing may be performed as described in relation to FIG. 1 and/or FIG. 2. For instance, the packing selection instructions 328 may cause a processor to determine a best packing in terms of values, fitness scores, quantities of packed objects, packing densities, and/or packing heights from a set (e.g., generation or generations) of chromosomes.

In some examples, the genetic procedure instructions 318 and/or packing selection instructions 328 may include code to cause the processor to rank chromosomes with hierarchical criteria based on values, fitness scores, quantities of packed objects, packing densities, and/or packing heights. The hierarchical criteria may include criteria with varying priority. For instance, the quantity of objects may be a criterion with a top priority and the fitness score may be a criterion with a next lower priority. In the hierarchical criteria, the processor may determine if there is a chromosome (e.g., placement, packing) with a best top priority criterion. If there is more than one chromosome with a best top priority criterion (e.g., multiple chromosomes with the same maximum quantity of packed objects), the selection may utilize the next lowest criterion. If there is more than one chromosome with a best next lowest criterion (e.g., multiple chromosomes with the same fitness scores or fitness scores within a range), the selection may utilize the next lower priority criterion (e.g., lowest priority).

To select a packing in some examples, packing scores may be compared. A packing score is a score indicating a value or a combination of values (e.g., quantity of objects packed, fitness score, packing height, and/or packing density, etc.). An example of packing selection is given as follows. Assume two packings A and B with corresponding packing scores s_A and s_B. In some examples, a packing score s_X may include parameters (e.g., k parameters or values): s_X={p1_X, p2_X, . . . , pk_X}, where px_X is a parameter or value. A quantity (e.g., k) of threshold values may be utilized: α, β, . . . , φ. If the first k−1 parameters of each packing are relatively closer to each other (up to an adjustable threshold), a Boolean value of (p1_A>p1_B) may indicate whether s_A is greater than s_B. For instance, In a case that abs(p1_A−p1_B)<α and abs(p2_A−p2_B)<β and so on for the rest of the parameters, and (pk_A !=pk_B), then a Boolean value of (pk_A>pk_B) may indicate whether s_A is greater than s_B. Otherwise, a parameter number k−1 may be compared. For instance, in a case that abs(p1_A−p1_B)<α and abs(p2_A−p2_B)<β and so on for the rest of the parameters, and (pk−1_A !=pk−1_B), then a Boolean value of (pk−1_A>pk−1_B) may indicate whether s_A is greater than s_B. Otherwise, similar comparisons may be made for a parameter or parameters (e.g., pk−2_A !=pk−2_B and so on) until the final case, where (p1_A>p1_B) may indicate whether s_A is greater than s_B. The packing with the greatest score may be selected. In some examples, one parameter or multiple parameters (e.g., values) may be utilized in the comparison.

In some examples, the computer-readable medium 330 may include code for causing a processor to manufacture the selected packing. For example, the code may cause a processor to execute instructions and/or send instructions to another device (e.g., 3D printer) to manufacture the selected packing.

FIG. 4 is a diagram illustrating an example of a user interface 434. The user interface 434 described in relation to FIG. 4 may be an example of the user interface(s) described herein. For instance, the user interface 434 may be an example of a user interface that may be produced and/or displayed by the apparatus 202 described in relation to FIG. 2. In this example, the user interface 434 includes a stop control 436 (e.g., button), a query interval control 438, a generation range control 440, a fitness control 442, a chromosome identifier selection control 444, a packing density plot 446, a packing height plot 448, and a quantity of packed objects plot 450.

In some examples, the user interface 434 may enable presenting values of chromosomes and providing a stop control 436. The user interface 434 may present tracked values at a chromosome level. For each chromosome in the population, for instance, the progress of the values may be tracked during evolution and/or execution of the genetic procedure.

In some examples, the user interface 434 may provide monitoring that interacts with a current execution of a genetic procedure instance. The user interface 434 may present (e.g., present to a user) the evolution of chromosome(s) over time (during execution of the genetic procedure, for instance). In some examples, the user interface 434 may allow a user to terminate the execution of the genetic procedure (by interacting with the stop control 436, for instance) when observing that an objective is reached or that the genetic procedure is stagnating.

In the example of FIG. 4, the user interface 434 includes three plots 446, 448, 450 (e.g., graphs, charts, etc.) illustrating monitoring and/or tracking of the progress of 120 chromosomes across 30 generations of the genetic procedure. The first plot 446 illustrates packing density on the vertical axis over generation on the horizontal axis. The second plot 448 illustrates packing height (e.g., z-height in mm) on the vertical axis over generation on the horizontal axis. The third plot 450 illustrates quantity of packed objects on the vertical axis over generation on the horizontal axis. In some examples, the quantity of chromosomes and/or the quantity of generations presented by the user interface 434 may correspond to the respective quantities of the current instance of the genetic procedure.

While some examples of tracked values are illustrated in FIG. 4, the user interface 434 may not be limited to tracking the tracked values illustrated. For example, a user interface may track quantity of unpacked objects, packed volume sum (e.g., sum of occupied volume), re-radiations score, and/or execution time, etc.

In some examples, the genetic procedure may produce a log. For instance, the genetic procedure may produce a comma-separated-values (csv) log. A log is data. For example, a log may be data indicating genetic procedure results and/or including chromosome details. The user interface 434 may read and/or interpret log content.

The user interface 434 may include a left side panel that includes three sections. The first section includes a stop control 436 (e.g., button) to allow a user to manually terminate the execution of the genetic procedure. The first section also includes a query interval control 438 to set a log read interval and/or frequency. In this example, the query interval control 438 includes a field (e.g., number field) and + and − buttons to set a query interval in seconds. In this example, the second section includes a generation range control 440, which may enable controlling plots with all the generations as they are computed or a most recent quantity. In this example, the generation range control 440 includes a checkbox, a field (e.g., a number field), and + and − buttons, where the checkbox controls whether to plot all generations, the field controls a quantity of last generations (e.g., the last 20, 30, 35, etc.) to plot, and the + and − buttons allow adding to or subtracting from the quantity of last generations. The third section includes a chromosome identifier selection control 444, which may enable plotting for a specific chromosome identifier or identifiers, or automatically plotting all the chromosomes. In this example, the chromosome identifier selection control 444 includes a “bf” checkbox. The “bf” checkbox may allow showing a best fitness chromosome (e.g., a chromosome a best value or chromosomes with best values over generations). The third section includes the fitness control 442. In this example, the fitness control 442 includes a “best fitness” checkbox, which may enable showing a curve with a best fitness. A “show all” checkbox may enable showing all curves corresponding to all chromosomes. In this example, the user interface 434 includes checkboxes for individual chromosomes (chromosome numbers 00, 01, 02, etc.). Checkboxes for chromosomes 00, 01, 02, 03, and best fitness are selected. Corresponding curves with a legend are included in the plots 446, 448, 450. For instance, some of the techniques described herein may monitor and/or track the evolution progress at a chromosome level, which may allow selecting a particular chromosome identifier to selectively visualize its corresponding progress on a user interface. In some examples, all of the chromosome identifiers may be selected, which may enable displaying all corresponding curves (e.g., evolutions of all chromosomes). In some examples, a best fitness (e.g., “bf”) curve may be a curve that illustrates the best packing (e.g., a chromosome with better and/or best features discovered so far). In some examples, the user interface 434 may include a filter field. The filter field may be utilized to indicate filtering (for interval filtering, for instance). In some examples, the user interface may include text labels for a control or controls, a section or sections, and/or an element or elements, etc. In some examples, another (e.g., different) control or controls may be included in an interface to provide a function or functions described herein.

In some examples, setting a termination condition or set of conditions (e.g., fitness score threshold, packing density threshold, packing height threshold, quantity of objects packed, maximum generation threshold, etc.) in a configuration file may be useful when a user has a guess about the quantity(ies) packings may achieve. The user interface 434 may enable run-time monitoring, which may provide a sense of the evolution progress in early generations and/or may enable modifying the termination condition or conditions on the fly to stop the evolution in the future.

In some examples, the genetic procedure results may be monotonically increasing (e.g., nondecreasing) from generation to generation. In some cases, it may be helpful to allow a genetic procedure to execute until reaching a maximum amount of generations (e.g., until consuming all pre-allocated computational time and/or resources). In some cases, the time cost of continuing to execute through all remaining generations may not be helpful, because the result quality may increase very slowly or may stagnate. Some of the techniques described herein may allow terminating a genetic procedure before reaching the maximum amount of generations (e.g., maximum threshold amount of generations) to provide a faster and/or more efficient genetic procedure. Some of the techniques described herein may include automated approaches (e.g., terminating based on a stagnant generation threshold) and/or approaches for providing a user interface.

It may be helpful to increase production throughput for 3D printing, which may reduce manufacturing cost. Some examples of the genetic procedure may be utilized for object packing based on values such as packing density, z-height, and/or thermal-aware features (e.g., minimization of re-radiation impacts). Genetic procedure convergence may depend on multiple factors like object pool geometry and packing parameters (e.g., population size, amount of elites, random seeding, etc.).

In some approaches, runtime computational resources may be pre-assigned via specifying population size and/or maximum generations for the evolution, where the genetic procedure may run through all the generations, report a best result, then terminate. To achieve faster packing, it may be helpful to terminate the genetic procedure before reaching the maximum generations (when convergence slows down significantly, for instance). Some of the techniques described herein may be automated (e.g., automatically terminating when reaching a stagnant generation threshold). For instance, the genetic procedure may be monitored at the chromosome level, which may allow automatically terminating the genetic procedure and/or packing. Some of the techniques described herein may provide a user interface to assist a user's judgement. For instance, a user interface may inform and/or aid a user to judge, and the user interface may receive an input to terminate the genetic procedure.

As used herein, the term “and/or” may mean an item or items. For example, the phrase “A, B, and/or C” may mean any of: A (without B and C), B (without A and C), C (without A and B), A and B (but not C), B and C (but not A), A and C (but not B), or all of A, B, and C.

While various examples are described herein, the disclosure is not limited to the examples. Variations of the examples described herein may be implemented within the scope of the disclosure. For example, aspects or elements of the examples described herein may be omitted or combined.

1. A method, comprising:
generating chromosomes in a genetic procedure, wherein each chromosome indicates a packing of objects in a volume;
determining a stagnant generation quantity that indicates an amount of generations subsequent to a leading generation with a leading chromosome score; and
terminating the genetic procedure based on the stagnant generation quantity.

2. The method of claim 1, further comprising comparing the stagnant generation quantity to a stagnant generation threshold.

3. The method of claim 1, terminating the genetic procedure is based on a set of conditions that comprises a stagnant generation threshold.

4. The method of claim 3, wherein the set of conditions further comprises a packed quantity threshold.

5. The method of claim 3, wherein the set of conditions further comprises a fitness score threshold.

6. The method of claim 3, wherein the set of conditions further comprises a packing height threshold.

7. The method of claim 3, wherein the set of conditions further comprises a packing density threshold.

8. The method of claim 3, wherein the set of conditions is a Boolean function.

9. The method of claim 1, wherein determining the stagnant generation quantity comprises:
determining whether a current chromosome score is better than the leading chromosome score;
in a case that the current chromosome score is better than the leading chromosome score, resetting the stagnant generation quantity and setting the leading chromosome score to the current chromosome score; and
in a case that the current chromosome score is not better than the leading chromosome score, incrementing the stagnant generation quantity.

10. An apparatus, comprising:
a memory;
a processor coupled to the memory, wherein the processor is to:
iterate a genetic procedure to generate chromosomes representing packings;
produce a user interface to display a tracked value of the chromosomes; and
determine whether to terminate the genetic procedure based on a stagnant generation quantity and whether a stop input from the user interface is detected.

11. The apparatus of claim 10, wherein the user interface comprises a stop control and a plot of the tracked value.

12. The apparatus of claim 11, wherein the user interface further includes a query interval control, a generation range control, and a chromosome identifier selection control.

13. A non-transitory tangible computer-readable medium storing executable code, comprising:
code to cause a processor to produce a current generation of chromosomes using a genetic procedure;
code to cause the processor to determine a current set of chromosome scores based on the current generation of chromosomes;
code to cause the processor to determine a stagnant generation quantity based on a comparison of a current best chromosome score to a previous leading chromosome score; and
code to cause the processor to determine whether to terminate the genetic procedure based on the stagnant generation quantity.

14. The computer-readable medium of claim 13, wherein the code to cause the processor to determine whether to terminate the genetic procedure comprises code to cause the processor to execute the genetic procedure until a logic rule is satisfied.

15. The computer-readable medium of claim 14, wherein the logic rule comprises a packed quantity threshold, a fitness score threshold, and a stagnant generation threshold.
